(19) United States
(12) Patent Application Publication
(10) Pub. No.: US 2026/0259669 A1
(43) Pub. Date: Sep. 3, 2026

(54) EFFICIENT POWER MANAGEMENT OF PARTIALLY PROGRAMMED VIRTUAL BLOCKS DURING READ OPERATIONS

(71) Applicant: Microchip Technology Incorporated, Chandler, AZ (US)

(72) Inventors: Pitamber Shukla, San Jose, CA (US); Nian Niles Yang, Mountain View, CA (US); Srinivas Yelisetti, Fremont, CA (US)

(73) Assignee: Microchip Technology Incorporated, Chandler, AZ (US)

(21) Appl. No.: 19/236,259

(22) Filed: Jun. 12, 2025

Related U.S. Application Data
(60) Provisional application No. 63/764,642, filed on Feb. 28, 2025.

(51) Int. Cl. G06F 3/06

(52) U.S. Cl. CPC G06F 3/0625; G06F 3/0655; G06F 3/0679

(57) ABSTRACT

A computer-implemented method and media for efficient power management of a data storage device including: receiving a host read request, identifying a virtual block (VB) included in the data storage device based on the host read request; determining an open block state of the identified VB, and performing a read operation on the identified VB corresponding to the host read request based on the determined open block state of the identified VB.

### CROSS REFERENCE TO RELATED APPLICATIONS

The current patent application claims the benefit under 35 U.S.C. § 119(e) of the priority date of U.S. Provisional Application Ser. No. 63/764,642 titled "EFFICIENT POWER MANAGEMENT OF PARTIALLY PROGRAMMED VIRTUAL BLOCKS DURING READ OPERATIONS" and filed February 28, 2025. The Provisional Application is hereby incorporated by reference, in its entirety, into the current patent application.

### TECHNICAL FIELD

Various examples of the present disclosure relate to methods and media for managing the power of data storage devices, such as NOT-AND (NAND) flash devices including solid-state drives (SSDs). Generally, the various examples described herein may be directed to power management of said data storage devices.

### BACKGROUND

Data storage devices, such as SSDs, may include non-volatile memory (NVM) media (e.g., NAND-based memory media) for data storage, and typically include application- specific integrated circuitry (ASIC) controllers for managing read, write (or program), erase, and other operations. Data storage devices may be used in enterprise computing data center solutions (DCS) and certain high-performance computing (HPC) applications, such as artificial intelligence (AI). It is generally desirable to improve performance and/or reduce the cost of data storage devices, but it may be difficult to do so. More particularly, the present disclosure seeks to improve performance, reliability, and quality of service (QoS) of data storage devices.

This background discussion is intended to provide information related to the presentinvention which is not necessarily prior art.

### SUMMARY OF THE INVENTION

According to various examples of the present disclosure, a computer-implemented method for efficient power management of a data storage device, such as an SSD or other NAND flash-based data storage device, may include: receiving a host read request; identifying, based on the host read request, a virtual block (VB) included in the data storage device; determining an open block state of the identified VB; and performing, based on the open block state of the identified VB, a read operation on the identified VB corresponding to the host read request.

According to various examples of the present disclosure, a non-transitorycomputer-readable media may have instructions embodied thereon which, when executed by one or more processors, cause the one or more processors to receive a host read request; identify, based on the host read request, a VB included in a data storage device; determine an open block state of the identified VB; and perform, based on the open block state of the identified VB, a read operation on the identified VB corresponding to the host read request.

This summary is not intended to identify essential features of the examples, and isnot intended to be used to limit the scope of the claims. These and other aspects of the present examples are described below in greater detail.

### BRIEF DESCRIPTION OF THE DRAWINGS

FIG. 1 illustrates an example environmental view of a system for managing power of and/or to a partially programmed VB included in a data storage device;

FIG. 2 illustrates an example computing system configured to perform operations in accordance with the various examples of the present disclosure;

FIG. 3 illustrates an example non-volatile memory (NVM) media in accordancewith the various examples of the present disclosure;

FIG. 4 illustrates a hierarchical view of an NVM media in accordance with thevarious examples of the present disclosure;

FIG. 5 illustrates an example multi-plane block of an NVM in accordance with the various examples of the present disclosure;

FIG. 6 illustrates an example multi-plane wordline (WL) of a multi-plane block in accordance with the various examples of the present disclosure;

FIG. 7 illustrates an example physical block of a data storage device in accordance with the various examples of the present disclosure; and

FIG. 8 illustrates an example method flow for managing power of and/or to a partially programmed VB of a data storage device in accordance with the various examples of the present disclosure.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particularmethod, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower, lateral, horizontal, vertical, and the like) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinaryskill in the art to practice the disclosed examples. The use of the terms "exemplary," "by example," and "for example," means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In various examples of the present disclosure, a data storage device may include adata storage component and a controller. While it may be preferable for the data storage device to be an SSD or other device including NAND flash-based non-volatile data storage media, other data storage devices (e.g., hard disk drives (HDDs), universal serial bus (USB) drives, secure digital cards (SD cards), micro-SD cards, etc.) are within the scope of the present disclosure.

The data storage device may be connected to a host system. In various examples,the data storage device may be connected to the host system by wired or wireless means. In various examples, the data storage device may be connected to more than one host system, such as in a multi-tenant environment, without limitation. The host system may be connected to more than one data storage device. The controller may be operable to manage storage and retrieval of data to and from the data storage device. The host system may send a command to the data storage device requesting that the data storage device transfer specific information stored thereon to the host, and/or that specific data be programmed (or written) to and/or read or erased from said data storage device. The controller may process (e.g., error correct) the specified data as desired (e.g., in accordance with firmware executing thereon and/or as commanded by the host).

In various examples, the data storage device may include a plurality of NVM media(e.g., NAND-based memory media) for data storage. The NVM media may include one or more local controllers. The NVM media may be organized into a plurality of blocks. A block of NVM media is the smallest unit of data that can be erased entirely. A block of NVM media may include an arrangement of a plurality of wordlines (WLs) and a plurality of bit lines (BLs).

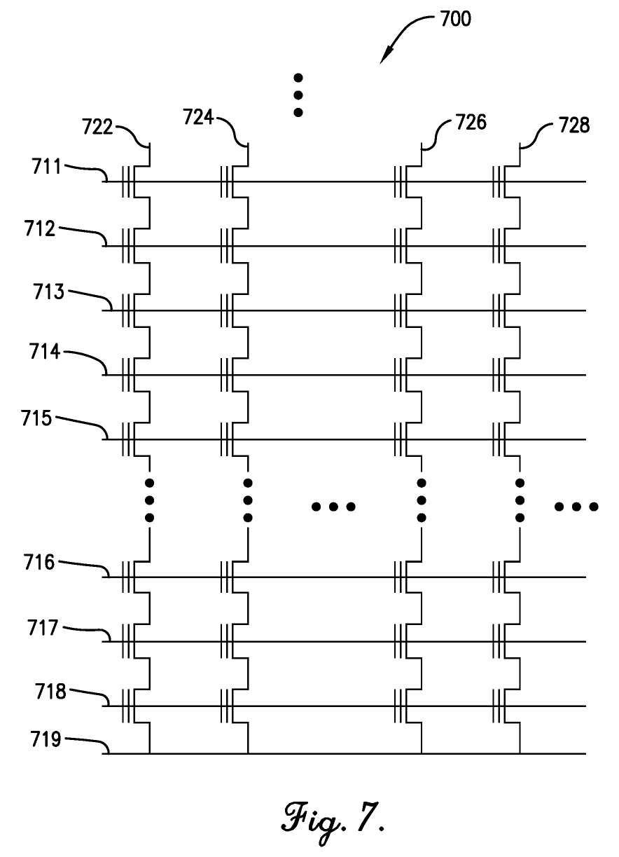

Generally, each WL is an electrical conductor that is electrically connected tocontrol gates of the cells in a respective row of cells. Each WL may convey an electronic signal that, according to its voltage level, selects a row (or page) of cells. (Each WL 711-718 may be drawn as a horizontal line shown in FIG. 7.) When a specific WL is activated (e.g., when a read voltage is applied), the cells connected to that WL are selected for reading or writing. In NAND flash memory, cells are organized into a series of strings, with each string being connected to one of the plurality of BLs, wherein each BL is an electrical conductor that is electrically connected to the drains of cells in a column of cells. Each BL may convey an electronic signal that, according to its voltage level, may enable data transfer to and from the cells of a selected WL during read and write operations. (Each BL 722-728 may be drawn as a vertical line shown in FIG. 7.) During a read operation, the voltage on the BL reflects a state of the selected cell(s). Accordingly, the voltage and/or current of the BL may be measured and/or determined to determine the value of the data in the selected cells.

In various examples, the data storage device may include chip enable (CE) ports. CE ports may enable (e.g., allow electrical signals to flow to and/or from) a physical block(s) of NVM media included therein.

A plurality of physical blocks of NVM media may be logically organized into a VB. Sometimes referred to as "superblocks", VBs may include one block from each plane of each logical unit (or logical unit number, or "LUN") included in the memory device. A VB may include the same block from each plane of each LUN (e.g., the first block of plane 1, the first block of plane 2, the first block of plane 3, etc.). Alternatively, a VB may mix block and plane numbers (e.g., the third block of plane 1, the fourth block of plane 2, the second block of plane 3, etc.).

Broadly, a LUN refers to a logical representation of a die included in a data storagedevice, such as a NAND flash device, where a "die" can be broadly defined as a physical chip and/or physical circuitry included (e.g., physically) in or otherwise corresponding to (e.g., logically) a LUN. Included in each LUN may be one or more planes. Generally, a plane may be represented as a vertical column within a memory device that includes a plurality of physical blocks, a page register, and a cache register. Physical blocks may store data, and comprise a plurality of pages. Data may be written to physical blocks on a page-by-page basis and erased on a block-by-block basis.

Generally, the number of VBs that can be formed within a data storage device equals the number of physical blocks in one plane of the device. VBs may include a plurality of virtual WLs (or VWLs), which can be broadly defined as an aggregation of (physical) WLs included in a VB. A VWL may span one page from each plane of each LUN included in the VB. The number of VWLs in a VB may be equivalent to the number of WLs in one physical block. In some examples, a VWL may include a number of WLs equal to the number of physical blocks in the VB.

Various examples of the present disclosure may be used in single-level cell (SLC) systems, but can also be used in higher level cell systems, such as triple-level cell (TLC), quadruple-level cell (QLC), and penta-level cell (PLC) systems. Applications for higher level cell systems may include, but are not limited to, high performance computing (HPC), data transfer for artificial intelligence (AI), and hyperscale SSDs and other data center solutions (DCS).

In various examples, a controller included in and/or communicatively coupled to adata storage device may efficiently manage the power of the data storage device. The controller may: receive a host read request; identify, based on the host read request, a VB included in the data storage device; determine an open block state of the identified VB; and perform, based on the determined open block state of the identified VB, a read operation on the identified VB corresponding to the host read request. The open block state of the identified VB may be fully closed (e.g., 100% programmed) or at least partially open (e.g., less than 100% programmed). The read operation may be performed on a target WL of the identified VB. The target WL may be a physical or virtual WL. Performing the read operation may include determining a voltage based on the open block state, and applying the determined voltage to the data storage device to perform the read operation, wherein the performed read operation corresponds to the host read request.

The voltage may be one of a pass-through voltage (Vpass) or a BL clamp voltage.In various examples, both a Vpass and a BL clamp voltage may be determined based on the open block state and applied to perform the read operation.

Broadly, a Vpass is a voltage that passes directly through a circuit, from input tooutput, as if there were zero (0) impedance in the circuit (e.g., as if a wire were shorting the input to the output). Application of a Vpass may ensure unselected WLs (UWLs) included in the block(s) of data storage device receiving the Vpass are "ON," or operating at the value of the applied Vpass. For instance, if a Vpass of eight (8) volts (V) were to be applied to a data storage device, then the data storage device would be considered "ON" if the device were operating at 8V. Generally, a Vpass that is applied to one or more UWLs of a block or VB of a data storage device that is being subjected to a read operation may be referred to as Vpass-read (or "Vpassr"). Application of a Vpassr may enable data from one or more cells of a selected WL or VWL (e.g., the WL or VWL that is being or about to be subjected to a read operation) to be transmitted via the BLs of the block or VB that is the target of the read operation.

A BL clamp voltage is typically a particular voltage value, or range of voltages, to which a BL in a semiconductor data storage device (e.g., a NAND flash device such as an SSD) is actively held by, for example, a clamping circuit coupled thereto. Application of a BL clamp voltage effectively ensures that the voltage applied to the BL(s) receiving the BL clamp voltage remains stable (e.g., at a specified value or within a specified range) during read and/or write operations, thereby enabling faster and more accurate data interpretation and transfer.

At any point in time, a data storage device may have allocated (e.g., via a hostsystem coupled thereto and/or via firmware executing thereon) to it a certain number, or balance, of power credits. Typically, a fixed power credit allocation exists for various input/output (I/O) commands, (e.g., read, write (or program), and/or erase commands) that may be executed on/by a data storage device. Broadly, a "power credit" can be thought of as a unit of currency that is consumed, or spent, from the total balance of power credits available to a data storage device when an I/O operation is performed on/by the data storage device. For example, a data storage device may have a total allocation, or balance, of one thousand (1,000) power credits; performing a read operation may consume one hundred (100) power credits; performing a write operation may consume two hundred (200) power credits; and performing an erase operation may consume three hundred (300) power credits. Conventionally, it is not possible to spend beyond the total power credit balance of a data storage device (e.g., the current total balance of power credits available to the data storage device cannot fall below zero (0)). As such, in the preceding example, any combination of read, write, and erase operations may be performed on/by the data storage device, so long as the sum of power credits consumed for performing said operations does not exceed 1,000.

Reducing the number of power credits consumed for any of the above-described I/O operations may allow for more efficient operation of the corresponding data storage device (e.g., by allowing more total operations to be performed on/by the device, or by decreasing the number of power credits required to perform a set number and/or sequence of operations on/by the device). According to the present disclosure, reducing one or more of a Vpass (more specifically, a Vpassr) or a BL clamp voltage applied to a data storage device to perform a read operation thereon may result in more efficient power credit allocation(s), and more efficient power management overall, for the affected data storage device.

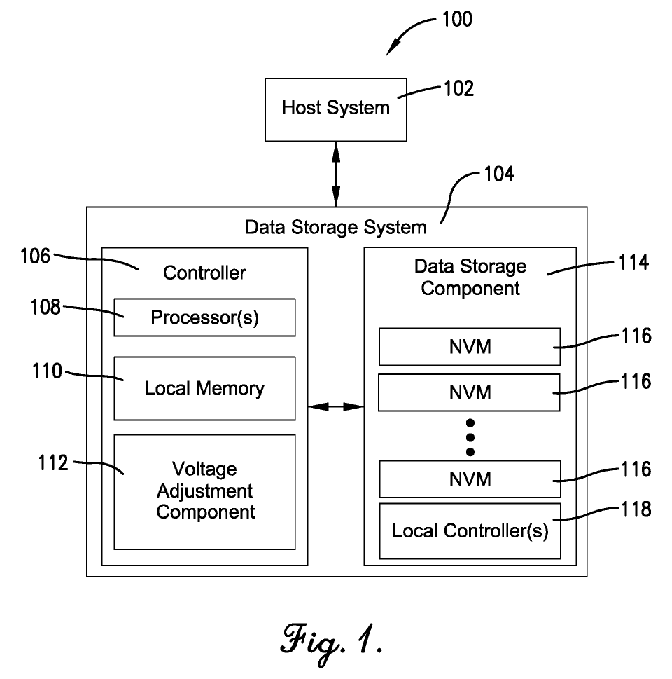

FIG. 1 illustrates an example system 100 including a host system 102 and a datastorage device 104. The data storage device 104 may include a controller 106 and a data storage component 114. According to the present disclosure, the data storage device 104 may be a NAND flash device, such as an SSD, and the controller 106 may be a flash controller. The controller 106 may include a processor 108, a local memory 110, and a voltage adjustment component 112. The data storage component 114 may include a plurality of non-volatile memory (NVM) media 116 and one or more local controller(s) 118. In various examples, the NVM 116 may be NAND-based flash memory. It would be appreciated by one of ordinary skill in the art that other types of memory (e.g., NOR flash memory, random access memory, and the like) may comprise the data storage component 114 and/or the NVM 116 included therein without departing from the spirit of the present disclosure.

In various examples, a host read request may be received by the data storage device 104 from the host system 102, e.g., via a peripheral component interconnect express (PCIe) interface that connects the data storage device 104 to servers or CPUs comprising the host system 102. The host read request may request that data from a specific location, such as a block, a VB, a cell(s), and/or an address(es) within the data storage device 104, be read. PCIe is a standardized interface for motherboard components. The controller 106 may use logical block addresses (LBAs) and physical block addresses (PBAs) to facilitate access for data storage in and retrieval from the NVM 116. LBAs are an abstraction to allow the operating system to interact with the NVM 116, and PBAs represent the actual hardware locations within the NVM 116. To facilitate interacting with the NVM 116, the controller 106 may create an entry or record that assigns an LBA to a PBA. To keep track of all such LBA-to-PBA assignments, the controller 106 may use a logical-to- physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a host read request is received from the host system 102, the controller 106 may reference the L2P mapping table to determine the PBA within the NVM 116 corresponding to a desired LBA. Once the PBA is determined, the controller 106 may access the appropriate NVM 116 to read the data specified in the host read request. Access to the NVM 116 may be via a flash physical (PHY) interface. The controller 106 may employ an error correction code (ECC) operation during encoding and decoding data to detect and correct errors and enhance data integrity. Additionally, the data storage component 114 may support a direct memory access (DMA) operation enabling data to be written from the host system 102 directly to the NVM 116 and read from the NVM 116 directly to the host system 102. Certain commands may be issued to the controller 106 or the local controller(s) 118 using the host command layer, or non-volatile memory express management interface (NVMe-MI).

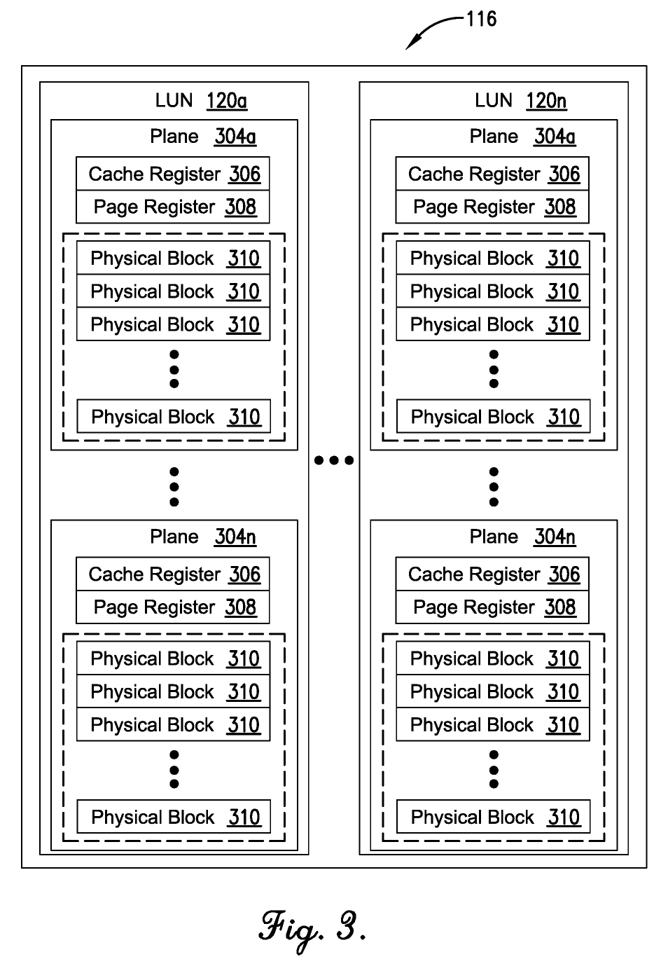

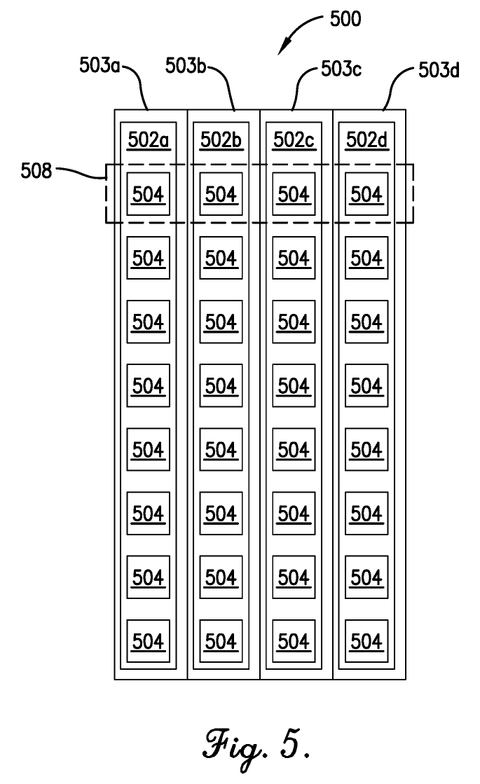

Each of the NVM 116 may include a plurality of LUINs (e.g., the LUJNs 120a through 120n of FIG. 3). Each LUN may include a plurality of planes (e.g., the planes 304a through 304n of FIG. 3). Each plane may include a plurality of physical blocks (e.g., the physical blocks 310 of FIG. 3). Each of the physical blocks 310 may include a set of pages (e.g., the pages 504 of FIG. 5). Each of the physical blocks 310 may include a set of WLs corresponding to the pages. Respective ones of the physical blocks 310 may be organized into a multi-plane block (e.g., the multi-plane block 500 of FIG. 5). Each multi-plane block may include one (1) physical block from each plane of one (1) LUN. Each multi-plane block may include a set of multi-plane WLs (e.g., the multi-plane WL 508 of FIG. 5). Each multi-plane WL may include corresponding WLs of the physical blocks included in a multi-plane block such that each multi-plane WL includes one (1) WL from each plane of the multi-plane block. User data may be written to the pages of a multi- plane WL.

In various examples, the arrangement of WLs and BLs included in the physical block 700 of FIG. 7 may be included in/comprise the physical blocks 310. Logical groupings of the blocks and/or WLs included in each of the NVM 116 may be formed to create VBs and/or VWLs, as described above and in more detail below.

In various examples of the present disclosure, the NVM 116 may further compriseone or more of a plurality of data cell, or memory cell, types - including an SLC memory cell configured to store one (1) bit of data, an MLC memory cell configured to store two (2) bits of data, a TLC memory cell configured to store three (3) bits of data, a QLC memory cell configured to sore four (4) bits of data, and/or a PLC memory cell configured to store five (5) bits of data.

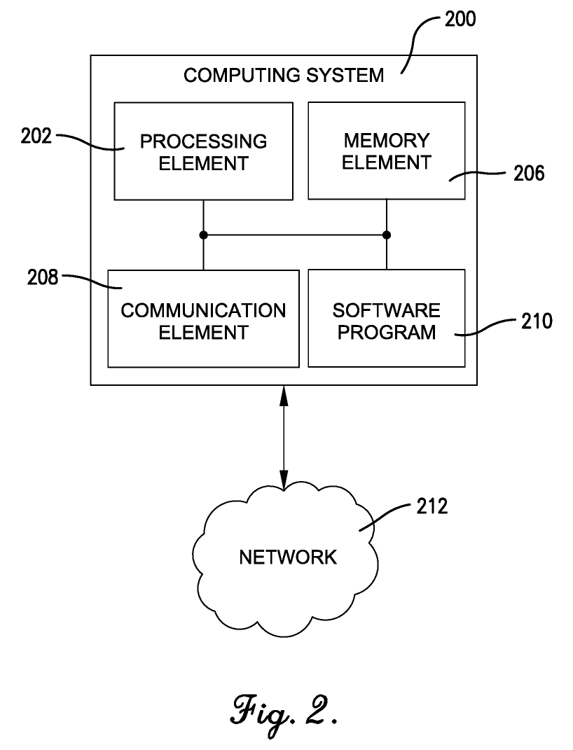

FIG. 2 illustrates a computing system 200 connected to a communication network212. The computing system 200 may include at least one processing element 202, at least one memory element 206, a communication element 208, and a software program 210. In various examples, the computing system 200 may be a host system (e.g., the host system 102 of FIG. 1) and/or a data storage system (e.g., the data storage device 104 of FIG. 1), without limitation.

The software program 210 may be configured with instructions for performingand/or enabling performance of at least some of the steps set forth herein. In an embodiment, the software program 210 comprises instructions stored on computer-readable media of memory element 206. In various examples, the software program 210 may include instructions for performing operations of the voltage adjustment component 112 discussed with reference to FIG. 1.

The communication network 212 generally allows communication between the computing system 200 and another computing device, such as between a remote host system (e.g., the host system 102), a local host system, and/or a data storage device(s) (e.g., the data storage device 104 of FIG. 1), without limitation. The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth^{TM}, or combinations thereof.

The communication element 208 generally allows communication between the computing system 200 and the communication network 212. The communication element 208 may include transmitter(s), receiver(s), and/or transceiver(s). The communication element 208 may also or alternatively include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard, such as WiFi, IEEE 802.16 standard, such as WiMAX, Bluetooth^{TM}, or combinations thereof. In addition, the communication element 208 may utilize communication standards such as ANT, ANT+, Bluetooth^{TM} low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain embodiments, the communication element 208 may also couple with optical fiber cables. The communication element 208 may respectively be in communication with the processing element 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof In some embodiments, the memory element 206 may be embedded in, or packaged in the same package as, the processing element 202. The memory element 206 may include, or may constitute, a "computer-readable medium." The memory element 206 may store the instructions, code, code segments, software, firmware, programs, applications, apps, services, daemons, or the like that are executed by the processing element 202. In an embodiment, the memory element 206 respectively store the software applications/program 210. The memory element 206 may also store settings, data, documents, sound files, photographs, movies, images, databases, and the like. In various examples, the memory element 206 may include a first memory component (e.g., the local memory 110 of FIG. 1) and one or more SSDs (e.g., the data storage component 114 of FIG. 1).

The processing element 202 may include electronic hardware components such asprocessors. The processing element 202 may include digital processing unit(s). The processing element 202 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 202 may generally execute, process, or run instructions, code, code segments, software, firmware, programs, applications, apps, processes, services, daemons, or the like. For instance, the processing element 202 may execute the software applications/program 210. The processing element 202 may also include hardware components such as finite-state machines, sequential and combinational logic, and other electronic circuits that can perform the functions necessary for the operation of the current disclosure. The processing element 202 may be in communication with the other electronic components through serial or parallel links that include universal busses, address busses, data busses, control lines, and the like.

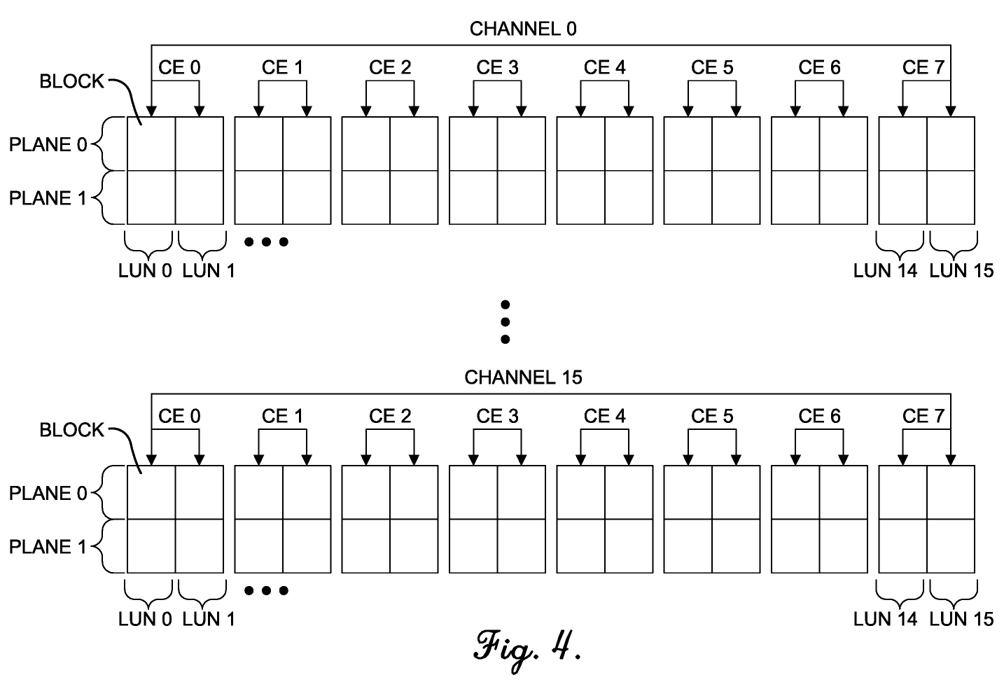

Turning to FIG. 3, the NVM 116 may respectively include a plurality of LUNs.. Asillustrated, the NVM 116 includes LUNs 120a, ... 120n, where 'a' and 'n' are integers. As such, each NVM 116 may include, for example, two (2), four (4), six (6), eight (8), or more LUNs, without limitation. For example, if the NVM 116 of FIG. 3 were to include sixteen (16) LUNs, LUNa might be represented as LUN 0 and LUNn might be represented as LUN 15. An example of an NVM including sixteen (16) LUNs (e.g., LUN 0 through LUN 15) is described in more detail in connection with FIG. 4. Each LUN 120a, ... 120n may include a plurality of planes 304a, ... 304n, again where 'a' and 'n' are integers. Each LUN 120a, ... 120n may include, for example, four (4), six (6), eight (8), or more planes, without limitation. Accordingly, if a particular LUN (e.g., LUN 0 of FIG. 4) were to include, as a non-limiting example, two (2) planes, those planes may be represented as plane 0 and plane 1 (e.g., as seen in LUN 0 of FIG. 4).

Each plane may include a cache register 306, a page register 308, and a plurality ofphysical memory blocks 310. In various examples, the controller 106 may write incoming data to more than one NVM 116 in parallel. The NVM 116 may write incoming data to more than one LUN in parallel.

When data is written to or retrieved from the NVM 116, the data may be temporarily stored in one of the cache register 306 and/or the page register 308. Each physical memory block 310 may include a set of pages (as described in connection with FIG. 5 below). The cache register 306 and the page register 308 may respectively have an equivalent data capacity of one page. Accordingly, data to be written to a first page may be temporarily stored in the cache register 306 while data to be written to another page may be temporarily stored in the page register 308. Data to be read from a first page may be retrieved and temporarily stored in the cache register 306 while data to be read from another page may be stored in the page register 308. Accordingly, the cache register 306 and page register 308 enable double buffering of data to reduce data programming and read times.

In various examples, the physical blocks 310 may be organized (e.g., logically grouped) into VBs. A VB may include at least one physical block from each plane of each LUN of each NVM 116 of the data storage component 114. Each VB may include a set of VWLs. Each VWL may correspond to a set of WLs (e.g., a VWL may include one (1) WL from each physical block of a VB). In various examples, the data processing and programming operations of this disclosure may be performed on a VB/VWL basis. Also or alternatively, the data processing and programming operations may be performed on a physical block/WL basis without departing from the spirit of the present disclosure.

FIG. 4 illustrates a hierarchical diagram of at least a portion of an NVM media, in accordance with the present disclosure. In various examples, FIG. 4 may illustrate the NVM 116 of FIG. 3, which in turn is a more detailed view of the NVM 116 included in the data storage component 114 of the data storage device 104 of FIG. 1. FIG. 4 depicts a plurality of blocks (e.g., the physical blocks 310 of FIG. 3 described above and/or the physical block 700 of FIG. 7 described below) of data storage configured in an array. All of the blocks in a row, which in this example includes sixteen (16) blocks, form a plane of data storage. As illustrated, a plane may span multiple CEs/CE lines (e.g., as Plane 0 of Channel 0 spans all sixteen (16) CE lines comprising the eight (8) CEs that are included in Channel 0). Two (2) blocks in a column (e.g., corresponding to/controlled by a CE line) form one (1) LUN, and two (2) LUNs, (e.g., LUN 0 and LUN 1) correspond to a CE (e.g., CE 0). Each of the sixteen (16) LUNs included in a channel (e.g., Channel 0) has a respective one of a plurality of CE lines (e.g., the left or right CE line comprising CE 0 through CE 7) electrically connected thereto, wherein each CE line receives a respective one of a plurality of CE signals. In addition, each CE line enables or disables a respective one of the LUNs (e.g., the left CE line of CE 0 may enable/disable LUN 0 and the right CE line of CE 7 may enable/disable LUN 15). Two (2) planes and eight (8) CEs form or correspond to a respective one of a plurality of channels, CHANNEL 0 through CHANNEL 15. In the illustrated exemplary diagram of a data storage system/device, there are two (2) planes associated with each LUN x two (2) LUNs per CEx eight (8) CEs per channel x sixteen (16) channels, resulting in 512 total blocks of data storage within the illustrated data storage device/system. The data storage device/system may take the form of a physical board, such as a printed circuit board or flexible circuit board, or a card of data storage, and, according to the present disclosure, may be the data storage system 104 of FIG. 1. It will be appreciated that: more or fewer than two (2) planes may be associated with a LUN, more or fewer than two (2) LUNs may be included in/associated with a CE, more or fewer than eight (8) CEs may be included in/associated with a channel, and that more or fewer than sixteen (16) channels may be included/associated with a data storage system/device.

FIG. 5 illustrates a multi-plane block 500 of an NVM (e.g., the NVM 116 of FIG. 1). The multi-plane block may include physical blocks 502a, 502b, 502c, 502d. The physical blocks 502a, 502b, 502c, 502d may be included in a set of planes 503a, 503b, 503c, 503d. Each physical block 502a, 502b, 502c, 502d may include a set of pages 504. A multi-plane WL 508 may be formed to include a page 504 of each physical block 502a, 502b, 502c, 502d.

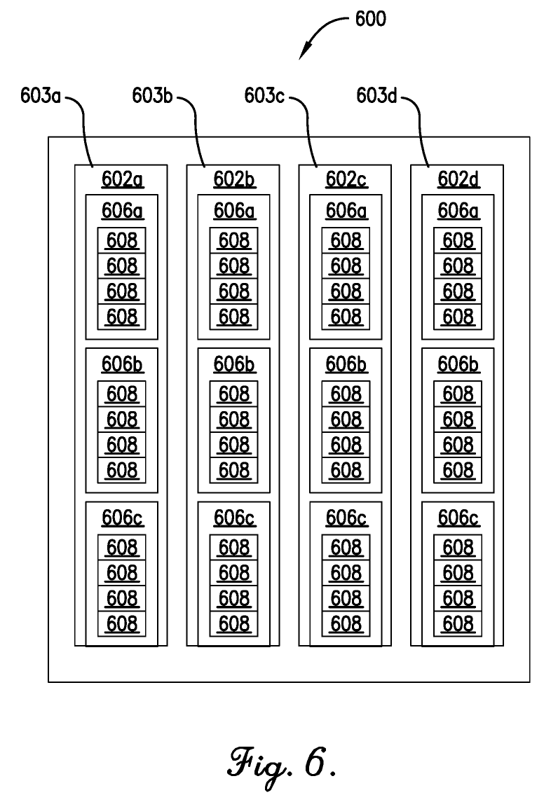

FIG. 6 illustrates a multi-plane WL 600 of a multi-plane block (e.g., the multi-planeblock 500 of FIG. 5). The multi-plane WL 600 may include pages 602a, 602b, 602c, 602d. The pages 602a, 602b, 602c,602d may be included in a set of physical blocks 603a, 603b, 603c, 603d that make up the multi-plane block. The pages 602a, 602b, 602c, 602d may be TLC pages that include TLC cells. Accordingly, each of the pages 602a, 602b, 602c, 602d may include an upper page 606a, a middle page 606b, and a lower page 606c. It would be appreciated by one of ordinary skill in the art that the pages 602a, 602b, 602c, 602d could include SLC pages, MLC pages, TLC, QLC pages, and/or PLC pages without departing from the spirit of the present disclosure. A plurality of data frames 608 may be stored in each of the upper pages 606a, middle pages 606b, and lower pages 606c.

According to the present disclosure, "virtual" versions of various structures, components, and/or sub-components of a NAND flash described above and below (e.g., virtual blocks, virtual wordlines, etc.) may be formed, generally speaking, by forming logical groupings of the corresponding physical structure, component, and/or sub-component described above in the discussion of FIGS. 1 - 6. For instance, generally speaking, a VB can be thought of as a logical grouping of physical blocks just as a VWL, generally speaking, is an aggregation of physical WLs included in the physical blocks grouped into a VB. These virtual constructs may be formed to reduce physical wear on the underlying and/or corresponding physical constructs, and/or to improve performance, reliability, QoS, etc. of the data storage device in which said virtual constructs are included/from which said virtual constructs are formed.

FIG. 7 depicts a physical block 700 of a data storage device that is comprised of aplurality of WLs (e.g., the WLs 711-718), a plurality of BLs (e.g., the BLs 722-728), and a ground or source line or plane 719. The physical block 700 may be included in the data storage device of FIG. 1, such as in a NAND flash device.

In some examples, the open block state of the physical block 700 may be either fully programmed or partially open, corresponding respectively, for example, to the "fully closed" or "at least partially open" open block states.

A plurality of the physical blocks 700 may be logically grouped together to form a VB. The WLs included in the physical blocks comprising the VB may be aggregated, or grouped, logically, into one or more VWL(s). While a physical WL is confined to a row of memory cells within a physical block of NAND flash, VWLs, being logical groupings of physical WLs, can span multiple physical WLs across multiple physical blocks, and even multiple CEs, CE lines and/or LUNs within a data storage device, allowing a controller (e.g., the controller 106 and/or one or more of the local controller(s) 118 of FIG. 1) coupled thereto to manage data more efficiently.

In some examples, the physical block 700 may be included in one or more of theNVM 116 of FIG. 1. Additionally and/or alternatively, the physical block 700 may comprise one or more of the "BLOCKS" depicted in FIG. 4. These physical blocks may be logically grouped into a VB, e.g., the VB discussed in the preceding paragraph. It is to be understood that the total number of physical blocks of memory included in the VB can equal the total number of physical blocks in one plane of the data storage device (e.g., the data storage device 104 of FIG. 1) that is being virtualized to form the VB.

According to various examples of the present disclosure, once a VB referenced in the host read command has been identified, an "open block state" of the identified VB is determined. The open block state of the identified VB may correspond to the "openness" of the VB, or a ratio/percentage representing how much of the identified VB is "open" (e.g., unprogrammed and/or erased) and/or how much is "closed" (e.g., programmed). The open block state of the identified VB may be one of "fully closed" (e.g., 100% of the identified VB is programmed) or at least "partially open" (e.g., the identified VB is less than 100% programmed). The open block state may be expressed as a binary (e.g., "closed" or "at least partially open") or as a percentage or decimal, for example corresponding to the percentage of the VB which is programmed or unprogrammed, without limitation.

The flash controller 106, the voltage adjustment component 112, and/or acombination thereof may determine a voltage that is to be applied to the identified VB based on the determined open block state of the VB identified in the host read request. In various examples, the determined voltage may be one of a Vpass or a BL clamp voltage. In various examples, both a Vpass and a BL clamp voltage are determined based on the open block state and applied in connection with a read operation.

The determined voltage may represent an adjustment comprising an offset from a default or otherwise applicable voltage based on the determined open block state of the identified VB. The offset to the default voltage may bring the determined voltage closer to zero (0) volts than the default voltage. For example, if a data storage device includes TLC memory cells, a default Vpassr of eight volts (8V) (e.g., Vpassr = 8V) may be defined (e.g., by a manufacturer) for performing read operations on the identified VB.

Embodiments of the present disclosure may, based on the determined open block state, determine an offset or other adjustment to the default voltage for use in performing a read operation on the identified VB. Under the example, if the open block state is "at least partially open," an offset may be computed and/or located (e.g., via an equivalent operation or in a lookup table, respectively). The offset may, for example, be a reduction of one and one half volts (1.5V). Application of the offset to the default Vpass voltage may lead to a determined Vpassr of six and one half volts (6.5V). Also or alternatively, a determined Vpassr may be more directly determined, without reference to an offset from the default voltage (e.g., via a lookup table containing Vpassrs which may be applied dependent on the value of the open block state and/or via equivalent operation taking the open block state as input and outputting the determined Vpassr(s)). The determined (adjusted) Vpassr may be applied to various UWLs during the read operation, as discussed in more detail below.

Similarly, a data storage device (e.g., one including TLC memory cells) may have a default BL clamp voltage of one volt (1V) for performing a read operation on a target WL of a VB. Again, the identified VB may be determined to be at least partially open. An offset or adjusted BL clamp voltage may be determined for the at least partially open VB. The offset or degree of adjustment may be two-tenths of one volt (0.2V). Subtracting this offset (0.2V) from the default BL clamp voltage of 1.OV would result in a determined or adjusted BL clamp voltage of eight- tenths of one volt (0.8V).

As noted above, the offset value or difference between a default voltage and determined voltage may depend on the value of the open block state. According to various examples, the determined or adjusted voltage for a VB with a higher degree of openness will represent an offset that is greater than that for a VB having a lower degree of openness (e.g., a default voltage for a VB that is 80% open may be adjusted by an offset that is greater than the offset that is applied to a VB that is only 25% open).

Because the value(s) of Vpassr(s) that can be applied to and/or handled by datastorage devices such as SSDs tend to be larger than the value(s) of BL clamp voltage(s) that can be applied to and/or handled by said devices, greater energy savings may be realized from, and wider latitude may be available for, adjustments to a default Vpassr. Accordingly, one approach may be to adjust a Vpassr to perform a read operation before adjusting a BL clamp voltage to perform the read operation. For example, reducing the value of a Vpassr by a certain amount, e.g., one half of one volt (0.5V), to perform a read operation may have the same impact on power credit consumption as decreasing a BL clamp voltage by the same amount to perform a read operation, regardless of the current value of any Vpassr and/or BL clamp voltage being applied to the data storage device being read.

According to the present disclosure, reducing the default Vpassr and/or default BL clamp voltage applied to an identified VB in order to perform the read operation may, in turn, reduce the amount of power credits consumed when performing the read operation. For instance, a read operation performed with the default Vpassr of 8V may consume one hundred (100) power credits whereas a read operation performed with the determined Vpassr of 6.5V may consume eighty-one (81) power credits.

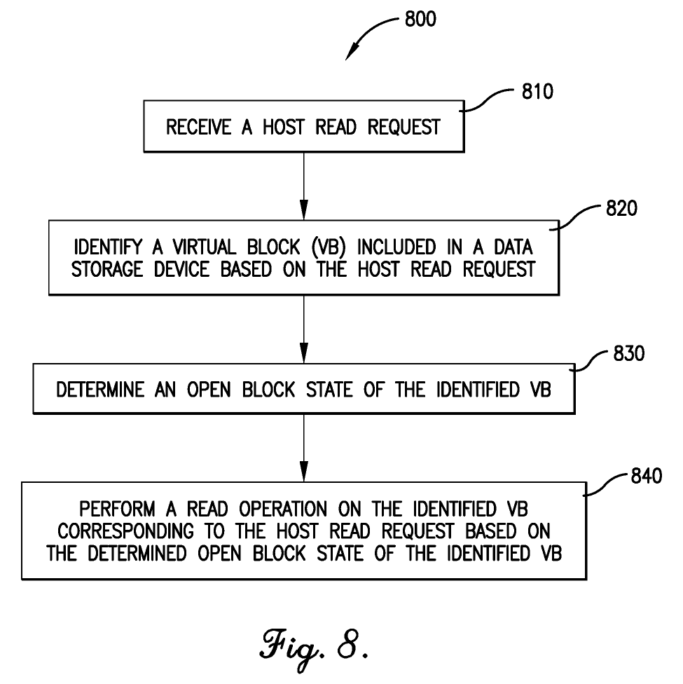

FIG. 8 illustrates an example method 800 for efficient power management of a data storage device, such as the data storage device 104 of FIG. 1. The method 800 may be performed on or by the data storage device (e.g., via one or more of the controller 106, the voltage adjustment component 112, and/or one or more of the local controllers 118 of FIG. 1). The steps may be performed in the order shown in FIG. 8, or they may be performed in a different order. Further, some steps may be performed concurrently as opposed to sequentially, and some steps may be optional.

While the method 800 may be performed by a host system (e.g., the host system 102) entirely, or a combination of the host system and a controller (e.g., the controller 106 and/or controller(s) 118 of FIG. 1) of a data storage device (e.g., the data storage device 104 of FIG. 1), the method 800 may be executed entirely by a controller. The method 800 may operate on a block of an NVM described in more detail above in connection with FIGS. 1-7. However, a person having ordinary skill will appreciate that responsibility for all or some of the operations described herein may be distributed differently among such devices or other computing devices included in and/or communicatively coupled to the system including the data storage device (e.g., the system 100 of FIG. 1) without departing from the spirit of the present disclosure.

The controller may manage storage and retrieval of data to and from a data storagedevice (e.g., the data storage device 104 of FIG. 1). The controller may identify, retrieve, process, and/or transmit data stored on the data storage device and/or the data storage component included therein (e.g., the data storage component 114 of FIG. 1) based on a host read request command received from the host system (e.g., the host system 102 of FIG. 1) according to the operations of method 800, as described in more detail below.

One or more computer-readable medium(s) may also be provided. The computer- readable medium(s) may include one or more executable programs stored thereon, such as firmware programs, wherein the program(s) instruct one or more processing elements to perform all or certain of the steps or operations outlined herein. The program(s) stored on the computer- readable medium(s) may instruct the processing element(s) to perform additional, fewer, or alternative actions, including those discussed elsewhere herein.

In various examples, the host system 102 may issue a host read command to acontroller 106 included in a data storage device 104. The host read command may be issued via any suitable communications network and/or protocol, including, but not limited to those discussed in connection with FIG. 2. At operation 810, the host read request is received by the data storage device 104. At operation 820, the flash controller 106 may identify a VB of NVM media (e.g., the NVM 116 of FIG. 1 and/or FIG. 3) included in the data storage device 104 based on (e.g., responsive to) the host read request. The VB of data storage device may correspond to the VB described in the discussion of FIG. 7 above.

At operation 830, the flash controller 106 may determine an open block state of the identified VB, wherein the state of the identified VB may correspond to the "openness" of the identified VB. According to the present disclosure, the open block state of the identified VB may correspond to whether the identified VB is either. (i) fully closed or (ii) at least partially open. An open block state of "fully closed" may correspond to the identified VB being fully (e.g., 100%) programmed while an open block state of "at least partially open" may correspond to the identified VB being less than 100% programmed. Firmware executing on the controller of the corresponding data storage device and/or the host system from which the host read request was received may be used to determine the open block state of the identified VB.

At operation 840, a read operation may be performed on the identified VBcorresponding to the host read request based on the determined open block state of the identified VB (e.g., the open block state determined during operation 830). According to examples of the present disclosure, including various examples described above, responsive to determining the open block state of the identified VB, a voltage may be determined. Application of the determined voltage to the target WL and/or application of the determined voltage to the BL may perform a read operation on the target WL. A controller, such as the controller 106 of FIG. 1, may be used in calculating the determined voltage. The determined voltage(s) may be one or both of a Vpass, such as a Vpassr, and/or a BL clamp voltage. In various examples, at least one Vpass (e.g., at least one Vpassr) and/or at least one BL clamp voltage may be determined based on the determined state of the identified VB. Firmware executing on the controller of the corresponding data storage device and/or the host system from which the host read request was received may be used to determine which of a Vpassr and/or BL clamp should be applied to the identified VB to perform the read operation.

More specifically, as in various examples described above, responsive to determining the identified VB is "fully closed," the data storage device may perform the corresponding read operation with one or more POR parameters. In various other examples, again as described above, responsive to determining the identified VB is "at least partially open," an offset or other adjustment may be applied to a default voltage, or another computation or lookup may be performed, in order to determine one or more appropriate adjusted voltages for performing the read operation.

In various examples, the determined voltage may correspond to a default voltage adjusted by an offset corresponding to the determined state of the identified VB. The offset may be used to adjust the value of the corresponding default voltage toward zero (0) volts (V). According to the present disclosure, the determined voltage for a VB with a higher degree of openness will represent an offset that is greater than that for a VB having a lower degree of openness (e.g., a default voltage for a VB that is 80% open may be adjusted by an offset that is greater than the offset that is applied to a VB that is only 25% open). As noted above, multiple determined voltages may be determined based on the determined state of the identified VB, including multiple determined Vpassrs and/or multiple BL clamp voltages. Firmware executing on the controller of the corresponding data storage device and/or the host system from which the host read request was received may be used to determine the value of the offset that is to be applied to the default voltage, and may be responsible for adjusting the default voltage by the offset to calculate the determined voltage.

As previously mentioned, the determined Vpassr may be applied on a VWL basis and/or may be applied on a WL basis. The determined Vpassr may be applied to one or more programmed unselected (e.g., not targeted) VWLs and/or unprogrammed unselected VWLs (e.g., all remaining unprogrammed unselected VWLs of the VB). For each block of the VB, the determined Vpassr may be applied to one or more programmed UWLs and/or unprogrammed UWLs (e.g., all remaining unprogrammed UWLs of the block), in any combination. In various examples, the determined Vpassr may be applied to one or more of the UWLs, another determined Vpassr may be applied to multiple other of the UWLs, and/or another Vpassr (e.g., a default or manufacturer-defined Vpassr, the value of which may be found, e.g., in a lookup table and/or included in, or based on, a power-on-reset parameter) may be applied to still other of the UWLs, in any combination.

Additional details for each of the method steps mentioned above can be found in the description of FIG. 1-7.

Through hardware, software, firmware, or various combinations thereof, any of the processing elements (e.g., of the controller 106 and/or local controller(s) of FIG. 1, the host system 102, and/or the processing element 202 of FIG. 2) may - alone or in combination with other processing elements - be configured to perform the operations of embodiments of the present disclosure. The embodiments described herein in connection with the attached drawing figures are intended to describe aspects of the disclosure in sufficient detail to enable those skilled in the art to practice the disclosure. Other embodiments can be utilized and changes can be made without departing from the scope of the present disclosure. The system may include additional, less, or alternate functionality and/or device(s), including those discussed elsewhere herein. The above and below detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

Additional processing may be performed as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

### FEATURE COMBINATIONS

According to various examples of the present disclosure, a computer-implemented method for efficient power management of a data storage device may comprise: receiving a host read request; identifying, based on the host read request, a virtual block (VB) included in the data storage device; determining an open block state of the identified VB; and performing, based on the determined open block state of the identified VB, a read operation on the identified VB corresponding to the host read request.

In combination with any of the previous examples, the open block state of the identified VB may correspond to the identified VB being one of: (i) fully closed or (ii) at least partially open.

In combination with any of the previous examples, the read operation may be performed on a target wordline.

In combination with any of the previous examples, performing the read operation may include determining a voltage based on the determined open blocks state that is applied to the data storage device.

In combination with any of the previous examples, the determined voltage may represent an adjustment based on the determined open block state of the identified VB.

In combination with any of the previous examples, the determined voltage maycorrespond to a default value adjusted with an offset.

In combination with any of the previous examples, the offset may adjust the default value toward zero (0) volts (V).

In combination with any of the previous examples, the computer-implemented method may further comprise calculating an adjusted power credit consumption based on the determined voltage applied to perform the read operation.

In combination with any of the previous examples, the open block state maycorrespond to the identified VB being fully closed, and the determined voltage may be identified as a power-on-reset parameter.

In combination with any of the previous examples, the determined voltage may be one of a pass-through voltage or a bitline clamp voltage.

In combination with any of the previous examples, the determined open block statemay correspond to the identified VB being at least partially open, and performing the read operation may include: determining an adjusted pass-through voltage and an adjusted bitline clamp voltage based on the determined open block state, applying the adjusted pass-through voltage to one or more unselected wordlines of the identified VB, and applying the adjusted bitline clamp voltage to a bitline of the identified VB.

According to various examples of the present disclosure, non-transitory computer- readable media having instructions stored thereon are provided which, when executed by one or more processors, cause the one or more processors to perform the steps comprising the computer- implemented method described above.

### GENERAL CONSIDERATIONS

In this description, references to "one embodiment", "an embodiment", "embodiments", "an example", "one example", or "examples" mean that the feature or features being referred to are included in at least one embodiment or example of the technology. Separate references to "one embodiment", "an embodiment", "embodiments", "an example", "one example", or "examples" in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application- specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term "processing element" or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general- purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element- implemented modules that operate to perform one or more operations or functions. The modulesreferred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as "processing," "computing," "calculating," "determining," "presenting," "displaying," or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms "comprises," "comprising," "includes," "including," "has," "having" or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, "or" refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as "means for" or "step for" language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A computer-implemented method for efficient power management of a data storage device, the method comprising:
receiving a host read request;
identifying, based on the host read request, a virtual block (VB) included in the data storage device;
determining an open block state of the identified VB; and
performing, based on the determined open block state of the identified VB, a read operation on the identified VB corresponding to the host read request.

2. The computer-implemented method of claim 1, wherein the open block state of the identified VB corresponds to the identified VB being one of: (i) fully closed or (ii) at least partially open.

3. The computer-implemented method of claim 1, wherein the read operation is performed on a target word line.

4. The computer-implemented method of claim 1, wherein performing the read operation includes determining a voltage based on the determined open block state that is applied to the data storage device.

5. The computer-implemented method of claim 4, wherein the determined voltage represents an adjustment based on the determined open block state of the identified VB.

6. The computer-implemented method of claim 4, wherein the determined voltage corresponds to a default value adjusted with an offset.

7. The computer-implemented method of claim 6, wherein the offset adjusts the default value toward zero (0) volts (V).

8. The computer-implemented method of claim 4, comprising calculating an adjusted power credit consumption based on the determined voltage applied to perform the read operation.

9. The computer-implemented method of claim 4, wherein the open block state corresponds to the identified VB being fully closed and the determined voltage is identified as a power-on-reset parameter.

10. The computer-implemented method of claim 4, wherein the determined voltage is one of a pass-through voltage or a bitline clamp voltage.

11. The computer-implemented method of claim 1, wherein the determined open block state corresponds to the identified VB being at least partially open, and performing the read operation includes - determining an adjusted pass-through voltage and an adjusted bitline clamp voltage based on the determined open block state,
applying the adjusted pass-through voltage to one or more unselected wordlines of the identified VB,
applying the adjusted bitline clamp voltage to a bitline of the identified VB.

12. Non-transitory computer-readable media having instructions embodied thereon which, when executed by one or more processors, cause the one or more processors to:
receive a host read request;
identify, based on the host read request, a virtual block (VB) included in a data storage device;
determine an open block state of the identified VB; and
perform, based on the determined open block state of the identified VB, a read operation on the identified VB corresponding to the host read request.

13. The non-transitory computer-readable media of claim 12, wherein the open block state of the identified VB corresponds to the identified VB being one of: (i) fully closed or (ii) at least partially open.

14. The non-transitory computer-readable media of claim 12, wherein the read operation is performed on a target word line.

15. The non-transitory computer-readable media of claim 12, wherein performing the read operation includes determining a voltage based on the determined open block state that is applied to the data storage device, the determined voltage being one of a pass-through voltage or a bitline clamp voltage.

16. The non-transitory computer-readable media of claim 15, wherein the determined voltage represents an adjustment based on the determined open block state of the identified VB, the determined voltage corresponding to a default value adjusted with an offset.

17. The non-transitory computer-readable media of claim 16, wherein the offset adjusts the default value toward zero (0) volts (V).

18. The non-transitory computer-readable media of claim 15, wherein executing the instructions causes the one or more processors to calculate an adjusted power credit consumption based on the determined voltage applied to perform the read operation.

19. The non-transitory computer-readable media of claim 15, wherein the open block state corresponds to the identified VB being fully closed and the determined voltage is identified as a power-on-reset parameter.

20. The non-transitory computer-readable media of claim 12, wherein the determined open block state corresponds to the identified VB being at least partially open, and performing the read operation includes - determining an adjusted pass-through voltage and an adjusted bitline clamp voltage based on the determined open block state,
applying the adjusted pass-through voltage to one or more unselected wordlines of the identified VB,
applying the adjusted bitline clamp voltage to a bitline of the identified VB.
